(19) United States
(12) Patent Application Publication
(10) Pub. No.: US 2016/0043092 A1
(43) Pub. Date: Feb. 11, 2016

(54) FIN FIELD-EFFECT TRANSISTOR STATIC RANDOM ACCESS MEMORY DEVICES WITH P-CHANNEL METAL-OXIDE-SEMICONDUCTOR PASS GATE TRANSISTORS

(71) Applicant: QUALCOMM Incorporated, San Diego, CA (US)

(72) Inventors: Niladri Narayan MOJUMDER, San Diego, CA (US); Stanley Seungchul SONG, San Diego, CA (US); Zhongze WANG, San Diego, CA (US); Choh Fei YEAP, San Diego, CA (US)

(21) Appl. No.: 14/454,805

(22) Filed: Aug. 8, 2014

(51) Int. Cl. H01L 27/11

(52) U.S. Cl. CPC H01L 27/1108; H01L 27/1116

(57) ABSTRACT

A complementary metal oxide semiconductor (CMOS) static random access memory (SRAM) cell. A CMOS SRAM cell in accordance with an aspect of the present disclosure includes a bit line and a word line. Such a CMOS SRAM memory cell further includes a CMOS memory cell having at least a first p-channel device comprising a first channel material that differs from a substrate material of the CMOS memory cell, the first channel material having an intrinsic channel mobility greater than the intrinsic channel mobility of the substrate material, the first p-channel device coupling the CMOS memory cell to the bit line and the word line.

### BACKGROUND

1. Field

Aspects of the present disclosure relate to semiconductor devices, and more particularly to a p-channel metal-oxide-semiconductor (PMOS) pass gate transistors in fin field-effect transistor (FinFET) static random access memory (SRAM) devices.

2. Background

The use of semiconductor materials for electronic devices is widespread. Many different materials, such as silicon (Si), gallium arsenide (GaAs), and other compound semiconductor materials may be used to create various types of devices, such as light emitting diodes, transistors, and solar cells, and may also be used to create integrated circuits including many individual devices.

In semiconductor devices, memory is often used to configure the functions of logic blocks and the routing of interconnections between devices and circuits. For power and size considerations, SRAM may be used to allow for customization of circuit operation.

SRAM memories may be fabricated from complementary metal-oxide-semiconductor (CMOS) circuits using field-effect transistor (FET) components. Recently, different structures for the transistors in CMOS have been introduced, where the transistor is a “fin” shaped (3D) structure. These structures are often referred to as “FinFET” structures.

There are some associated problems with CMOS memory applications. The difference in charge carrier mobility in p-channel devices with respect to n-channel devices is heightened in faster CMOS memory applications.

### SUMMARY

A complementary metal oxide semiconductor (CMOS) static random access memory (SRAM) cell in accordance with an aspect of the present disclosure includes a bit line and a a word line. Such a CMOS SRAM memory cell further includes a CMOS memory cell having at least a first p-channel device comprising a first channel material that differs from a substrate material of the CMOS memory cell, the first channel material having an intrinsic channel mobility greater than the intrinsic channel mobility of the substrate material, the first p-channel device coupling the CMOS memory cell to the bit line and the word line.

A complementary metal oxide semiconductor (CMOS) static random access memory (SRAM) cell in accordance with another aspect of the present disclosure includes a CMOS memory cell having a bit line and a word line. Such a CMOS SRAM memory cell further includes means for coupling the CMOS memory cell to the bit line and the word line, in which the means for coupling has an intrinsic channel mobility higher than the intrinsic channel mobility of a substrate material of the CMOS memory cell.

A method for making a complementary metal oxide semiconductor (CMOS) static random access memory (SRAM) cell in accordance with an aspect of the present disclosure includes coupling a CMOS memory cell to a bit line with a first p-channel device. Such a method further includes coupling the CMOS memory cell to a word line with the first p-channel device, in which the first p-channel device comprises a channel material that differs from a substrate material, the channel material having an intrinsic channel mobility higher than the intrinsic channel mobility of the substrate material.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer in an aspect of the present disclosure.

FIG. 2 illustrates a cross-sectional view of a die in accordance with an aspect of the present disclosure.

FIG. 3 illustrates a cross-sectional view of a metal-oxide-semiconductor field-effect transistor (MOSFET) device in an aspect of the present disclosure.

FIG. 4 illustrates a transistor in accordance with an aspect of the present disclosure.

FIGS. 5A-5C illustrate schematics of CMOS memory cells.

FIG. 6 illustrates a schematic of a CMOS memory cell in an aspect of the present disclosure.

FIG. 7A illustrates a cross-sectional view of a PMOS device in accordance with an aspect of the present disclosure.

FIG. 7B illustrates a top-down view of a CMOS memory cell in accordance with an aspect of the present disclosure

FIG. 8 is a process flow diagram illustrating a method for fabricating a device on a semiconductor substrate according to an aspect of the present disclosure.

FIG. 9 is a block diagram showing an exemplary wireless communication system in which a configuration of the disclosure may be advantageously employed.

FIG. 10 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Semiconductor fabrication processes are often divided into three parts: a front end of line (FEOL), a middle of line (MOL) and a back end of line (BEOL). Front end of line processes include wafer preparation, isolation, well formation, gate patterning, spacers, and dopant implantation. A middle of line process includes gate and terminal contact formation. Back end of line processes include forming interconnects and dielectric layers for coupling to the FEOL devices. These interconnects may be fabricated with a dual damascene process using plasma-enhanced chemical vapor deposition (PECVD) deposited interlayer dielectric (ILD) materials. Various materials may be used in FEOL, MOL, or BEOL processes to increase performance of the semiconductor devices.

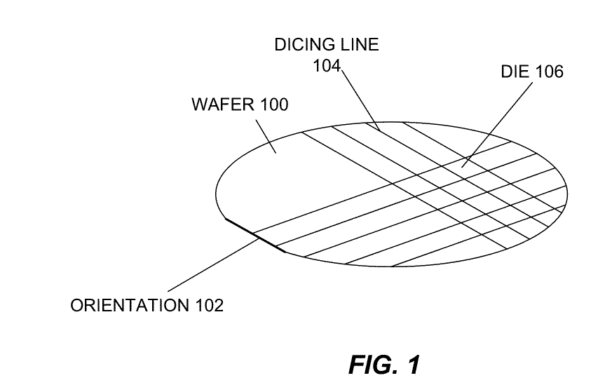

FIG. 1 illustrates a perspective view of a semiconductor wafer in an aspect of the present disclosure. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a compound material, such as gallium arsenide (GaAs) or gallium nitride (GaN), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and l, which are the Miller indices for a plane (hkl) in the crystal. Each index denotes a plane orthogonal to a direction (h, k, l) in the basis of the reciprocal lattice vectors. The integers are usually written in lowest terms (e.g., their greatest common divisor should be 1). Miller index (100) represents a plane orthogonal to direction h; index 010 represents a plane orthogonal to direction k, and index 001 represents a plane orthogonal to l. For some crystals, negative numbers are used (written as a bar over the index number) and for some crystals, such as gallium nitride, more than three numbers may be employed to adequately describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

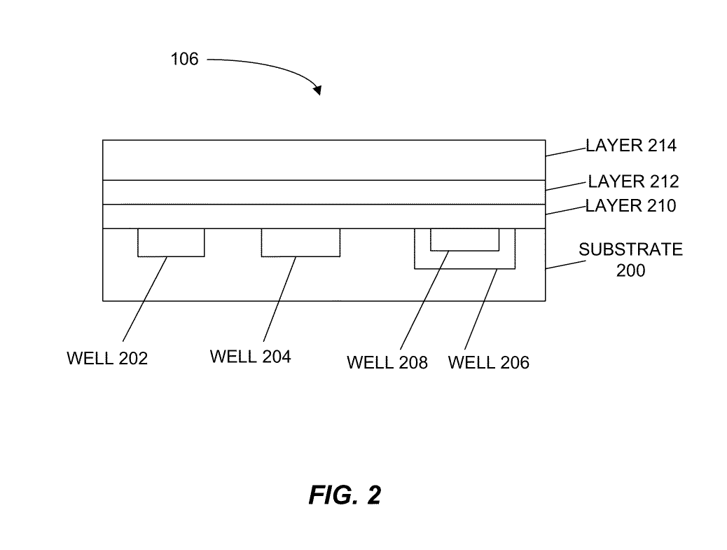

FIG. 2 illustrates a cross-sectional view of a die 106 in accordance with an aspect of the present disclosure. In the die 106, there may be a substrate 200, which may be a semiconductor material and/or may act as a mechanical support for electronic devices. The substrate 200 may be a doped semiconductor substrate, which has either electrons (designated n-type) or holes (designated p-type) charge carriers present throughout the substrate 200. Subsequent doping of the substrate 200 with charge carrier ions/atoms may change the charge carrying capabilities of the substrate 200.

Within a substrate 200 (e.g., a semiconductor substrate), there may be wells 202 and 204, which may be the source and/or drain of a field-effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have wells 206 and 208. The well 208 may be completely within the well 206, and, in some cases, may form a bipolar junction transistor (BJT). The well 206 may also be used as an isolation well to isolate the well 208 from electric and/or magnetic fields within the die 106.

Layers 210 through 214 may be added to the die 106. The layer 210 may be, for example, an oxide or insulating layer that may isolate the wells 202-208 from each other or from other devices on the die 106. In such cases, the layer 210 may be silicon dioxide, a polymer, a dielectric, or another electrically insulating layer. The layer 210 may also be an interconnection layer, in which case it may be a conductive material such as copper, tungsten, aluminum, an alloy, or other like conductive material.

The layer 212 may also be a dielectric or conductive layer, depending on the desired device characteristics and/or the materials of the layers 210 and 214. The layer 214 may be an encapsulating layer, which may protect the layers 210 and 212, as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may include many features or structural components. For example, the die 106 may be exposed to any number of methods to impart dopants into the substrate 200, the wells 202-208, and, if desired, the layers 210-214. For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers 210-214, and through selective removal, material selection, and dopant concentration of the substrate 200 and the wells 202-208, many different structures and electronic devices may be formed within the scope of the present disclosure.

Further, the substrate 200, the wells 202-208, and the layers 210-214 may be selectively removed or added through various processes. Chemical wet etching, chemical mechanical planarization (CMP), plasma etching, photoresist masking, damascene processes, and other methods may create the structures and devices of the present disclosure.

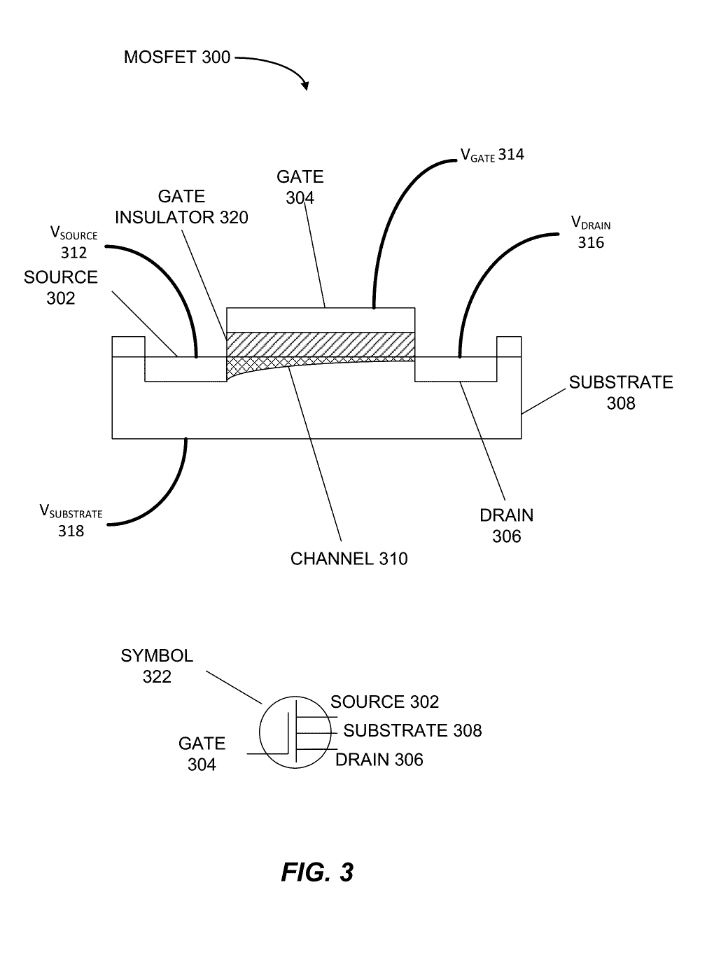

FIG. 3 illustrates a cross-sectional view of a metal-oxide-semiconductor field-effect transistor (MOSFET) device 300 in an aspect of the present disclosure. The MOSFET device 300 may have four input terminals. The four inputs are a source 302, a gate 304, a drain 306, and a substrate 308. The source 302 and the drain 306 may be fabricated as the wells 202 and 204 in the substrate 308, or may be fabricated as areas above the substrate 308, or as part of other layers on the die 106 if desired. Such other structures may be a fin or other structure that protrudes from a surface of the substrate 308. Further, the substrate 308 may be the substrate 200 on the die 106, but substrate 308 may also be one or more of the layers 210-214 that are coupled to the substrate 200.

The MOSFET device 300 is a unipolar device, as electrical current is produced by only one type of charge carrier (e.g., either electrons or holes) depending on the type of the MOSFET device 300. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314 or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a greater potential than that of the voltage Vdrain 316. Making the voltage differential between the voltage Vsource 312 and the voltage Vdrain 316 larger changes the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For n-type MOSFETs (using electrons as charge carriers in the channel 310), an arrow is applied to the substrate 308 terminal in the symbol 322 pointing away from the gate 304 terminal. For p-type MOSFETs (using holes as charge carriers in the channel 310), an arrow is applied to the substrate 308 terminal in the symbol 322 pointing toward the gate 304 terminal.

The gate 304 may also be made of different materials. In some designs, the gate 304 is made from polycrystalline silicon, also referred to as polysilicon or poly, which is a conductive form of silicon. Although referred to as “poly” or “polysilicon” herein, metals, alloys, or other electrically conductive materials are contemplated as appropriate materials for the gate 304 as described in the present disclosure.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304 as described in the present disclosure.

Conductive interconnects (e.g., traces) can be used for interconnection to the MOSFET device 300, or for interconnection to other devices in a die 106 (e.g., a semiconductor die). These conductive interconnect traces may be in one or more of layers 210-214, or may be in other layers of the die 106.

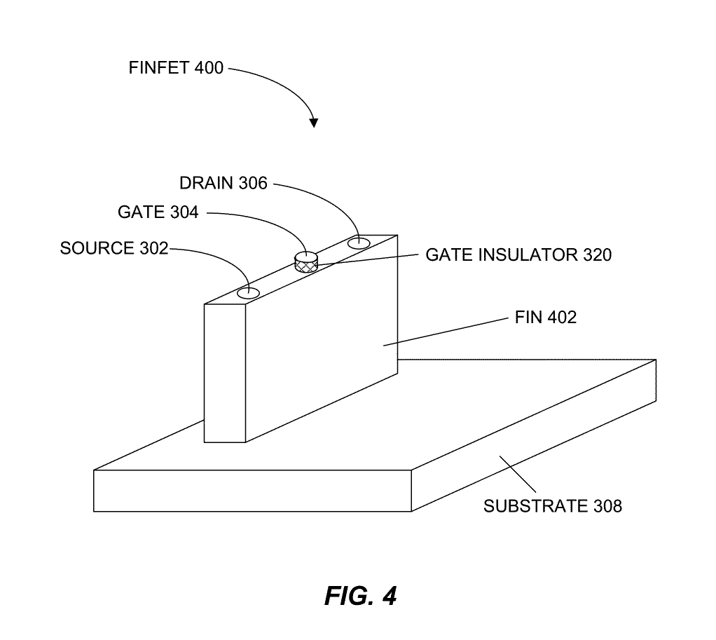

FIG. 4 illustrates a transistor in accordance with an aspect of the present disclosure. A fin-structured FET (FinFET 400) operates in a similar fashion to the MOSFET device 300 described with respect to FIG. 3. A fin 402 in a FinFET 400, however, is grown or otherwise coupled to the substrate 308. The fin 402 includes the source 302, the gate 304, and the drain 306. The gate 304 is coupled to the fin 402 through the gate insulator 320. In a FinFET structure, the physical size of the FinFET 400 may be smaller than the MOSFET device 300 structure shown in FIG. 3. This reduction in physical size allows for more devices per unit area on the die 106.

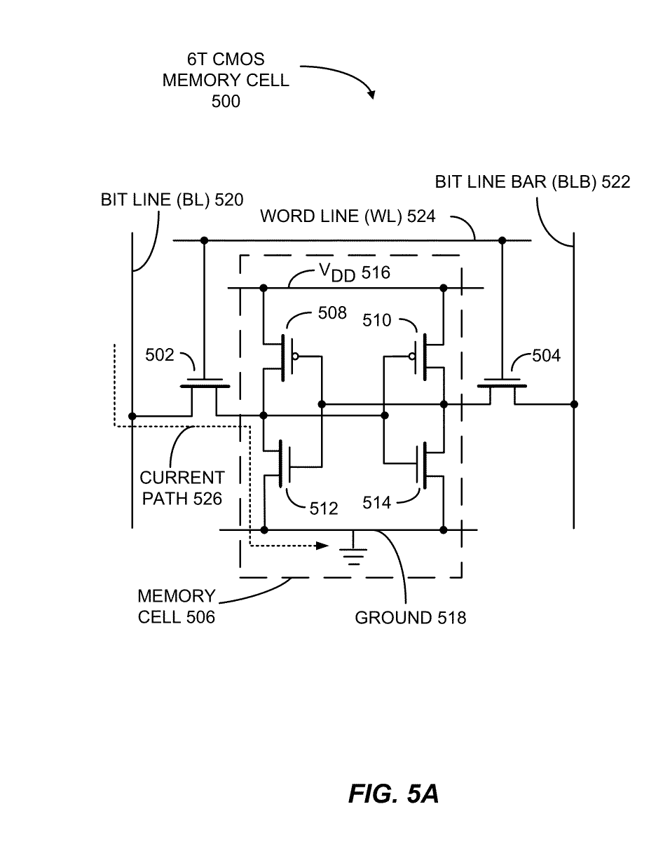

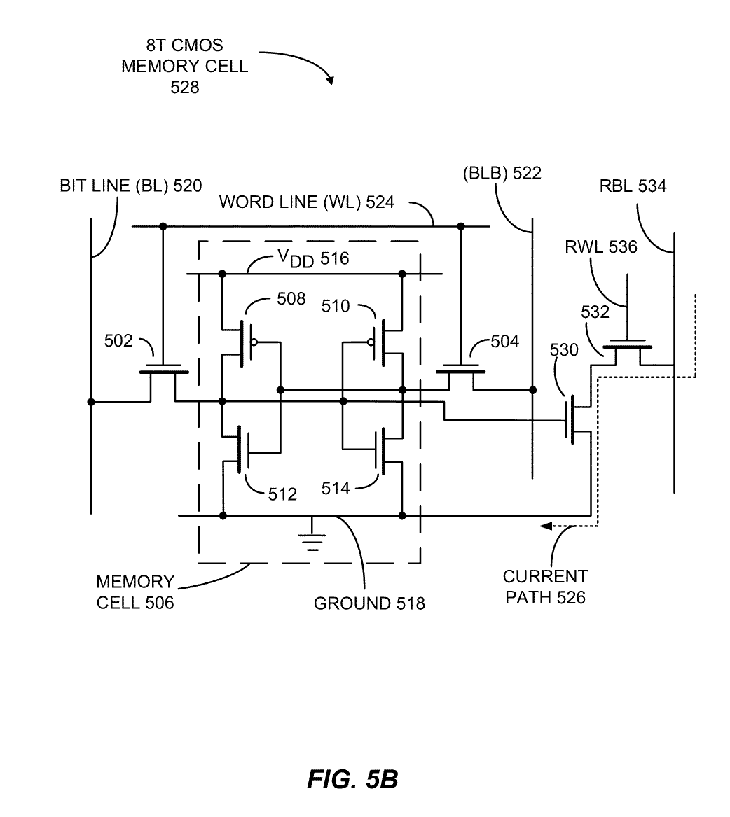

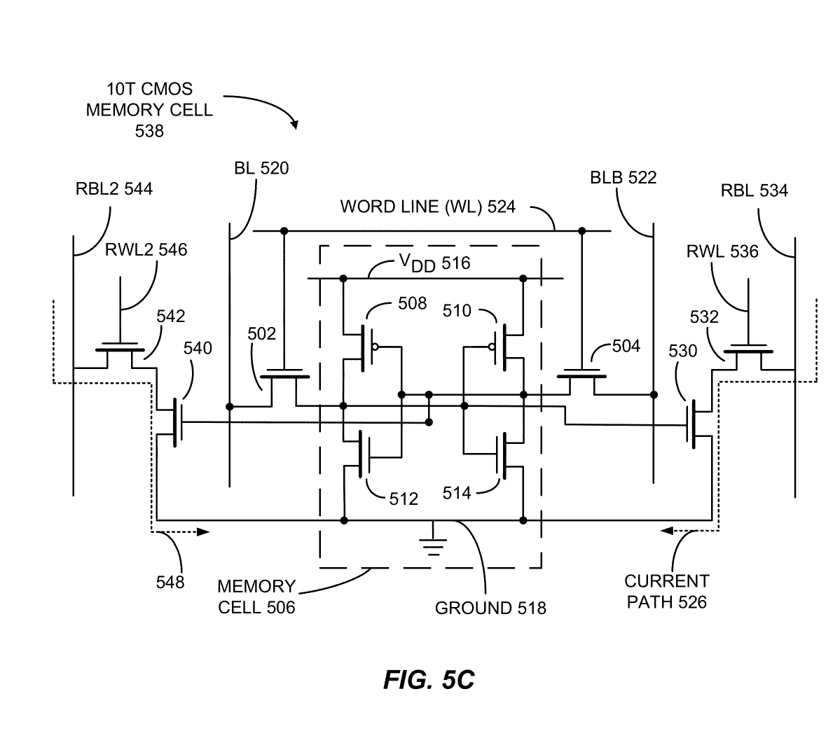

FIG. 5A illustrates a schematic of a CMOS memory cell 500. FIG. 5A illustrates a six transistor (6T) cell (also known as a single port cell). In FIG. 5A, pass gate transistors 502 and 504 are n-channel (NMOS) devices. A memory cell 506 includes a first p-channel pull-up transistor 508 and a second p-channel pull-up transistor 510, and also includes a first NMOS pull-down transistor 512 and a second NMOS pull-down transistor 514. The first p-channel pull-up transistor 508 and the second p-channel pull-up transistor 510 are coupled to a supply voltage (VDD) 516. In addition, the first NMOS pull-down transistor 512 and the second NMOS pull-down transistor 514 are coupled to ground 518.

The pass gate transistor 502 source and drain are coupled between the memory cell 506 and a bit line (BL) 520. The pass gate transistor 504 source and drain are coupled between the memory cell 506, and a bit line bar (BLB) 522. The gates of the pass gate transistors 502 and 504 are coupled to a word line (WL) 524.

To read the memory cell 506, the voltage on the word line 524 is raised, which may be to the voltage of the supply voltage 516. Raising the voltage of the word line 524 provides voltage to the gate of the pass gate transistor 502. This opens the channel in the pass gate transistor 502. Current flows from the bit line 520 through the pass gate transistor 502, and then through the first NMOS pull-down transistor 512 to ground 518. A current path 526 is shown to indicate the direction and path of the current flow through the CMOS memory cell 500 during a read operation.

FIG. 5B illustrates an eight transistors (8T) (dual port) CMOS memory cell 528. In CMOS memory cell 528, additional NMOS transistors 530 and 532 are employed for reading the memory cell 506. To read the memory cell 506, the read bit line (RBL) 534 is set high, and the read word line 536 is also set high, which may be to VDD 516. This allows the current path 526 to be opened and the memory cell 506 to be read.

FIG. 5C illustrates a ten transistor (10T) (three port) CMOS memory cell 538. In CMOS memory cell 538, two more additional NMOS transistors 540 and 542 are employed for reading the memory cell 506. To read the memory cell 506, the second read bit line (RBL2) 544 is set high, and the read word line 546 is also set high, which may be to VDD 516. This allows the current path 548 to be opened and the memory cell 506 to be read.

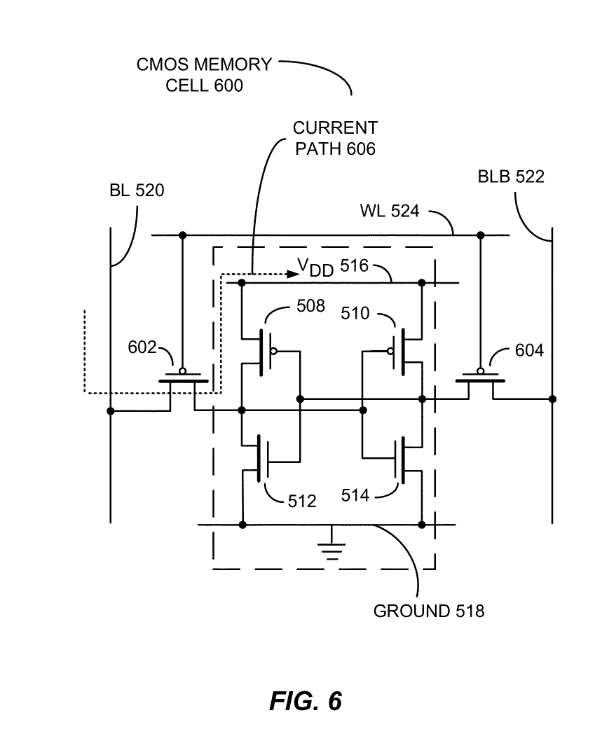

FIG. 6 illustrates a schematic of a CMOS memory cell 600 in an aspect of the present disclosure. In FIG. 6, p-channel (PMOS) devices are used as a first PMOS pass gate device 602 and a second PMOS pass gate device 604 for the CMOS memory cell 600. The first PMOS pass gate device 602 and the second PMOS pass gate device 604 are shown as transistors in FIG. 6, but may be other devices. When a read operation is performed on the CMOS memory cell 600, a voltage on the word line 524 is reduced instead of increased. The voltage on the word line 524 may be reduced to zero volts. Further, voltages on the bit line 520 and bit line bar 522 are also reduced, and may also be reduced to zero volts. These voltage conditions open the channel in the first PMOS pass gate device 602. Current flows from the bit line 520 through the first PMOS pass gate device 602, and then through the first p-channel pull-up transistor 508 to the supply voltage (VDD) 518. The present disclosure contemplates employing PMOS devices for pass gate devices 602 and/or 604, as well as, alternatively or collectively, employing PMOS devices within the scope of the present disclosure for transistors 530, 532, 540, and/or 542.

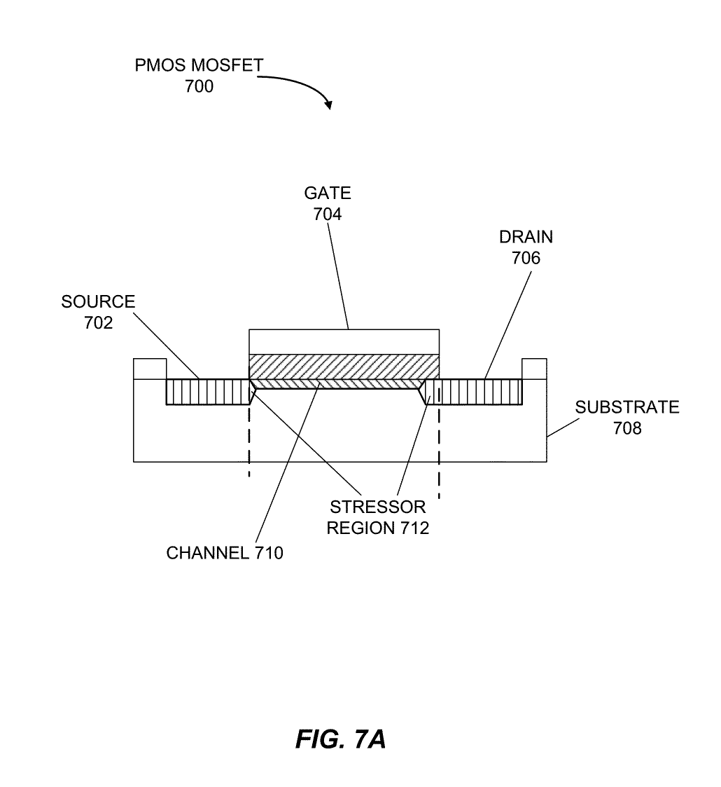

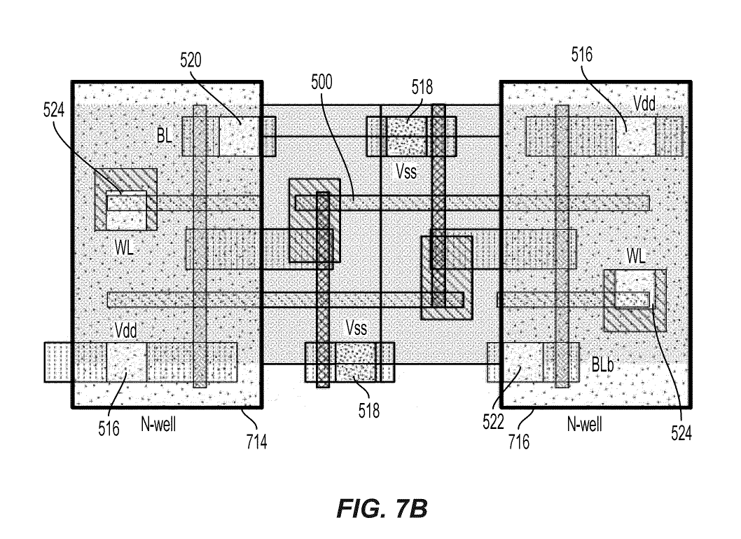

FIG. 7A illustrates a cross-sectional view of a PMOS device in accordance with an aspect of the present disclosure. A PMOS MOSFET device 700 includes a source 702, a gate 704, a drain 706, and a semiconductor substrate 708. Although shown as a planar device, the PMOS MOSFET device 700 may be a FinFET device or a gate-all-around nanowire device without departing from the scope of the present disclosure.

In the PMOS MOSFET device 700, electrical current through the channel is produced by holes, and as such the source 702 and the drain 706 are materials that are missing a valence electron in the atomic outer shell. In a silicon-based PMOS device, the source 702 and drain 706 may be doped silicon, where the dopant(s) are from Group III of the periodic table (i.e., boron, aluminum, gallium, indium, and/or tellurium). In other semiconductor material systems, the material used either as a dopant or as the underlying material may be from other periodic table groups.

In the PMOS MOSFET device 700, the source 702 and/or the drain 706 may include stressor geometries and/or stressor materials to increase the charge carrier mobility in the channel 710. For example, and not by way of limitation, in a semiconductor substrate 708 composed of silicon, silicon germanium (SiGe) may be a material in the source 702 and/or drain 706 to provide stress on the channel 710. The difference in the lattice geometries, as well as the difference in atomic size and atomic bond length between SiGe and silicon provides a compressive stress on the channel 710. The stress on the channel 710 increases the hole mobility through the channel 710.

As shown in FIG. 7A, the source 702 and/or the drain 706 may also have irregular shapes, such as saw tooth shapes, grooves, curved shapes, or other shapes or portions of the source 702 and/or drain 706 that lie underneath the gate 704. Such stressor regions 712 help increase the stress on the channel 710.

In an aspect of the present disclosure, the channel 710 may also include different materials to increase the stress in the channel 710. For example, SiGe may also be in the channel 710 to provide additional stress throughout the channel 710, which would further increase the hole mobility in the PMOS MOSFET device 700. The stressor regions 712 and different materials in the channel 710, source 702, and/or drain 706, increase the carrier mobility through the PMOS MOSFET device 700 over that of a channel 710 composed of silicon (e.g., in a silicon-based MOSFET device). In other words, the channel 710 may have a material, geometry, or other property that has an intrinsic channel mobility greater than an intrinsic channel mobility of the semiconductor substrate 708.

Because NMOS devices and PMOS devices have different charge carrier mobility, different materials may be used for PMOS devices than for NMOS devices. One of the materials in PMOS devices is silicon-germanium (SiGe), but other materials, such as Group III-Group V (III-V) binary materials, II-VI materials, or other materials having a channel mobility higher than that of silicon may be employed in the p-channel device portions of CMOS devices.

By increasing the channel 710 charge carrier mobility of the PMOS MOSFET device 700, when used as the first PMOS pass gate device 602 and/or the second PMOS pass gate device 604, or as the first p-channel pull-up transistor 508 and/or the second p-channel pull-up transistor 510, the carrier mobility through the PMOS portions of a CMOS device are increased. As such, the speed through the CMOS memory cell 600 for a read operation is increased. Similar speed increases are realized for write operations, because the current is flowing through devices having a carrier mobility greater than that of the silicon NMOS devices in the CMOS memory cells.

Because these improvements are at the bit cell level, the overall Static Random Access Memory (SRAM) bitcell/array performance and reliability are improved. These improvements will be applicable regardless of scaling of the devices, because the materials are not as affected by lithography as other speed improvement techniques.

Although SiGe is described in FIGS. 5, 6, and 7A, any other semiconductor material composition having a higher carrier mobility than that of silicon may realize the improvements and structures of the present disclosure. Having greater carrier mobility through multiple devices within the CMOS memory cell 600 increases the read/write speeds and improves cell write margins over NMOS-pass gate devices. This technique also improves FinFET performance in small geometries (e.g., below 14 nanometers), where SRAM performance tends to degrade due to supply voltage scaling and higher current variations.

For example, and not by way of limitation, a SiGe PMOS pull up (PU) transistor (e.g., The first p-channel pull-up transistor 508 and/or the second p-channel pull-up transistor 510) in the CMOS memory cell 600 improves the minimum read voltage (Read Vmin) of the SRAM bit cell by ˜10%. A SiGe PMOS pass gate (PG) transistor 602/604 improves the SRAM read performance and write margin (WRM) (e.g., by ˜20% and ˜40%, respectively).

Si—Ge channel PMOS pass gate transistors 602/604 also offer a built-in guard band against negative bias temperature insensitivity (NBTI) degradation. NBTI severely degrades the CMOS memory cell 600 read stability (e.g., minimum read voltage, Vmin) over time. This reliability improvement is based on a reduced interaction between channel carriers and defects in the gate dielectric in the pass gate and pull up transistors. These performance enhancements may be realized in any CMOS SRAM memory cell, such as a 6T SRAM cell, an 8T SRAM cell, and a 10T SRAM cell. Further, the SRAM cell may be a planar device, a FinFET device, or a gate-all-around nanowire device.

FIG. 7B illustrates a top-down view of a CMOS memory cell in accordance with an aspect of the present disclosure. The CMOS memory cell 500 includes an n-well 714 and an n-well 716. The PMOS MOSFET device 700 may be included within the n-wells 714 and 716. In the n-well 714, devices (e.g., the first PMOS pass gate device 602 and the first p-channel pull-up transistor 508) are coupled to the bit line 520, the supply voltage 516 (e.g., VDD) and the word line 524. In the n-well 716, devices (e.g., second PMOS pass gate device 604 and the second p-channel pull-up transistor 510) are coupled to the bit line bar 522, the supply voltage 516, and the word line 524. The CMOS memory cell 500 also includes the first NMOS pull-down transistor 512 and the second NMOS pull-down transistor 514, coupled to V_{SS} (e.g., ground 518), and to the n-wells 714 and 716, as shown in FIG. 6.

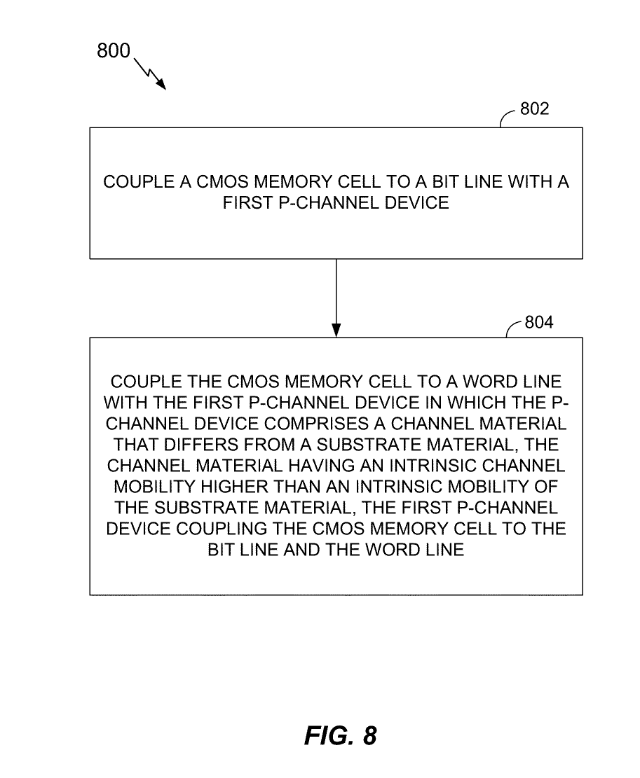

FIG. 8 is a process flow diagram illustrating a method 800 for fabricating a device on a semiconductor substrate according to an aspect of the present disclosure. In block 802, a CMOS memory cell is coupled to a bit line with a first p-channel device. In block 804, the CMOS memory cell is coupled to a word line with the first p-channel device. The first p-channel device includes a first channel material that differs from a substrate material of the CMOS memory cell. The first channel material has an intrinsic channel mobility greater than the intrinsic channel mobility of the substrate material. In addition, the first p-channel device couples the CMOS memory cell to the bit line and the word line, for example, as shown in FIG. 6.

According to a further aspect of the present disclosure, a complementary metal oxide semiconductor (CMOS) static random access memory (SRAM) cell is described. In one configuration, the CMOS SRAM cell includes a CMOS memory cell having a bit line and a word line. The CMOS SRAM cell may be, for example, the memory cell 506 as shown in FIG. 5. The CMOS SRAM cell also includes a bit line and a word line. The bit line may be the bit line 520 and the word line may be the word line 524 as shown in FIG. 5. The CMOS SRAM cell also includes means for coupling the CMOS memory cell to the bit line and the word line. The means for coupling has an intrinsic channel mobility greater than the intrinsic channel mobility of a substrate of the CMOS memory cell. The coupling means may be, for example, the first PMOS pass gate device 602 as shown in FIG. 6. In another aspect, the aforementioned means may be any module or any apparatus configured to perform the functions recited by the aforementioned means.

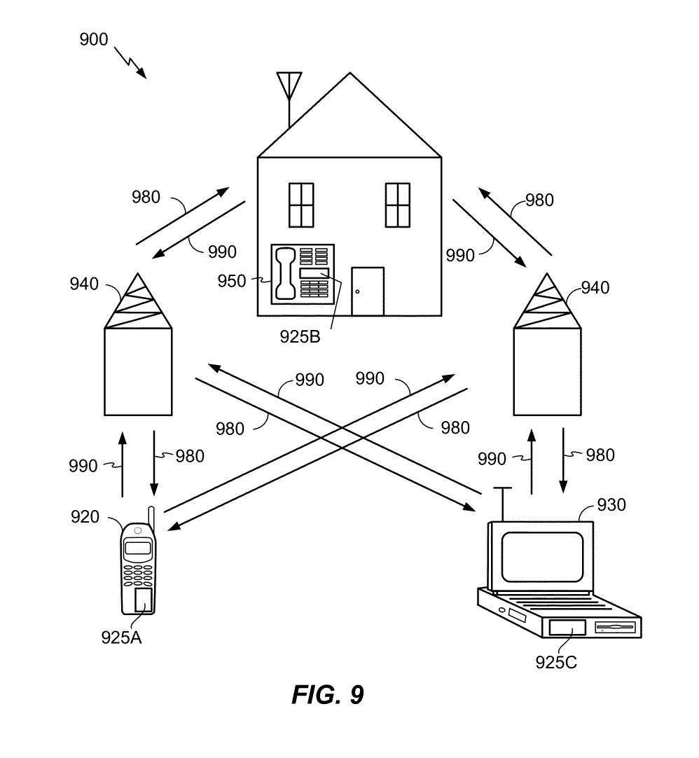

FIG. 9 is a block diagram showing an exemplary wireless communication system 900 in which an aspect of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include IC devices 925A, 925C, and 925B that include the disclosed PMOS transistors. It will be recognized that other devices may also include the disclosed PMOS transistors, such as the base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a fixed location remote unit in a wireless local loop system. For example, a remote unit may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as meter reading equipment, or other devices that store or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices, which include the disclosed devices.

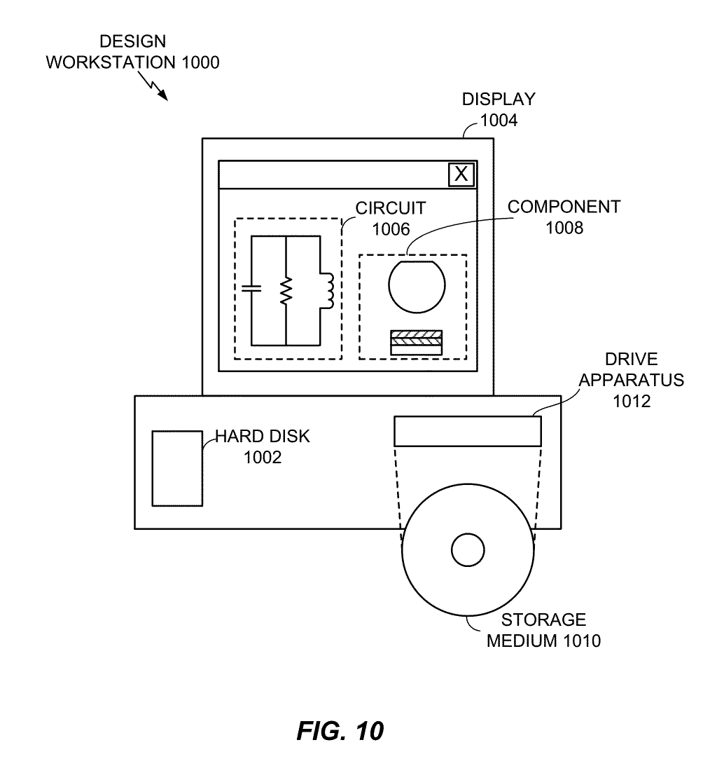

FIG. 10 is a block diagram illustrating a design workstation used for circuit, layout, and logic design of a semiconductor component, such as the devices disclosed above. A design workstation 1000 includes a hard disk 1002 containing operating system software, support files, and design software such as Cadence or OrCAD. The design workstation 1000 also includes a display 1004 to facilitate design of a circuit 1006 or a semiconductor component 1008 such as a PMOS transistor of the present disclosure. A storage medium 1010 is provided for tangibly storing the design of the circuit 1006 or the semiconductor component 1008. The design of the circuit 1006 or the semiconductor component 1008 may be stored on the storage medium 1010 in a file format such as GDSII or GERBER. The storage medium 1010 may be a CD-ROM, DVD, hard disk, flash memory, or other appropriate device. Furthermore, the design workstation 1000 includes a drive apparatus 1012 for accepting input from or writing output to the storage medium 1010.

Data recorded on the storage medium 1010 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1010 facilitates the design of the circuit 1006 or the semiconductor component 1008 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A complementary metal oxide semiconductor (CMOS) static random access memory (SRAM) cell, comprising:
a bit line;
a word line; and
a CMOS memory cell having at least a first p-channel device comprising a first channel material that differs from a substrate material of the CMOS memory cell, the first channel material having an intrinsic channel mobility greater than the intrinsic channel mobility of the substrate material, the first p-channel device coupling the CMOS memory cell to the bit line and the word line.

2. The CMOS SRAM cell of claim 1, in which the first channel material comprises SiGe.

3. The CMOS SRAM cell of claim 1, in which the first channel material comprises a III-V material.

4. The CMOS SRAM cell of claim 1, comprising at least one of a six transistor (6T) SRAM cell, an eight transistor (8T) SRAM cell, and a ten transistor (10T) SRAM cell.

5. The CMOS SRAM cell of claim 1, in which the CMOS SRAM cell is a planar device.

6. The CMOS SRAM cell of claim 1, in which the CMOS SRAM cell is a FinFET device.

7. The CMOS SRAM cell of claim 1, in which the CMOS SRAM cell is a gate-all-around nanowire device.

8. The CMOS SRAM cell of claim 1, further comprising a bit line bar and a second p-channel device, in which the CMOS memory cell is coupled to the bit line bar by the second p-channel device.

9. The CMOS SRAM cell of claim 8, in which the second p-channel device comprises a second channel material that differs from the substrate material of the CMOS memory cell, and in which the intrinsic channel mobility of the second channel material is greater than the intrinsic channel mobility of the substrate material of the CMOS memory cell.

10. The CMOS SRAM cell of claim 1, integrated into a mobile phone, a set top box, a music player, a video player, an entertainment unit, a navigation device, a computer, a hand-held personal communication systems (PCS) unit, a portable data unit, and/or a fixed location data unit.

11. A complementary metal oxide semiconductor (CMOS) static random access memory (SRAM) cell, comprising:
a CMOS memory cell having a bit line and a word line; and
means for coupling the CMOS memory cell to the bit line and the word line, in which the means for coupling has an intrinsic channel mobility higher than the intrinsic channel mobility of a substrate material of the CMOS memory cell.

12. The CMOS SRAM cell of claim 11, in which the coupling means comprises SiGe.

13. The CMOS SRAM cell of claim 11, in which the coupling means comprises a III-V material.

14. The CMOS SRAM cell of claim 11, comprising at least one of a six transistor (6T) SRAM cell, an eight transistor (8T) SRAM cell, and a ten transistor (10T) SRAM cell.

15. The CMOS SRAM cell of claim 11, in which the CMOS SRAM cell is a planar device.

16. The CMOS SRAM cell of claim 11, in which the CMOS SRAM cell is a FinFET device.

17. The CMOS SRAM cell of claim 11, in which the CMOS SRAM cell is a gate-all-around nanowire device.

18. The CMOS SRAM cell of claim 11, further comprising a bit line bar and a second means for coupling the CMOS memory cell to the bit line bar.

19. The CMOS SRAM cell of claim 18, in which the intrinsic channel mobility of the second coupling means is greater than the intrinsic channel mobility of the substrate material of the CMOS memory cell.

20. The CMOS SRAM cell of claim 11, integrated into a mobile phone, a set top box, a music player, a video player, an entertainment unit, a navigation device, a computer, a hand-held personal communication systems (PCS) unit, a portable data unit, and/or a fixed location data unit.

21. A method for making a complementary metal oxide semiconductor (CMOS) static random access memory (SRAM) cell, comprising:
coupling a CMOS memory cell to a bit line with a first p-channel device; and
coupling the CMOS memory cell to a word line with the first p-channel device, in which the first p-channel device comprises a channel material that differs from a substrate material, the channel material having an intrinsic channel mobility higher than the intrinsic channel mobility of the substrate material.

22. The method of claim 21, further comprising coupling a second p-channel device between the CMOS memory cell and a bit line bar.

23. The method of claim 22, in which the second p-channel device comprises a second channel material that differs from the substrate material, and in which the intrinsic channel mobility of the second channel material is greater than the intrinsic channel mobility of the substrate material of the CMOS memory cell.

24. The method of claim 21, further comprising integrating the CMOS SRAM cell into a mobile phone, a set top box, a music player, a video player, an entertainment unit, a navigation device, a computer, a hand-held personal communication systems (PCS) unit, a portable data unit, and/or a fixed location data unit.
